(19) United States
(12) Patent Application Publication
(10) Pub. No.: US 2026/0170213 A1
(43) Pub. Date: Jun. 18, 2026

(54) INFORMATION DEVICE, SYSTEMS, INFORMATION METHOD, AND PROGRAMS

(71) Applicant: Renesas Electronics Corporation, Tokyo (JP)

(72) Inventor: Hitoshi HAMAO, Tokyo (JP)

(21) Appl. No.: 19/358,816

(22) Filed: Oct. 15, 2025

(30) Foreign Application Priority Data
Dec. 12, 2024 (JP) 2024-217299

(51) Int. Cl. G06F 30/3308; G06F 1/04

(52) U.S. Cl. CPC G06F 30/3308; G06F 1/04

(57) ABSTRACT

A configuration unit 20 includes: a storage unit 21 that stores RTL waveform data 21a, which shows the waveforms of multiple signals output from the RTL simulator 10 simulating the operation of the first model representing the target circuit; a determination unit 25A; and a generation unit 26. The multiple signals include a clock signal. The determination unit 25A determines, by analyzing the RTL waveform data 21a, a mask time period during which one or more analysis target signals, other than the clock signal, among the multiple signals do not fluctuate. The generation unit 26 generates an input signal to the model simulator 12, which simulates the operation of the second model obtained by converting the first model. The generation unit 26 generates a masked clock signal as an input signal by masking the mask time period in the clock signal.

### CROSS-REFERENCE TO RELATED APPLICATIONS

The disclosure of Japanese Patent Application No. 2024-217299 filed on December 12, 2024, including the specification, drawings and abstract is incorporated herein by reference in its entirety.

### BACKGROUND

The present disclosure relates to an information processing device, system, information processing method, and program, which can be suitably used, for example, in an information processing device, system, information processing method, and program that support the verification of a model representing a target circuit.

There are disclosed techniques listed below.

Patent Document 1 Japanese Unexamined Patent Application Publication No. 2002-22808

In recent years, the use of model-based design has been increasing in the development of integrated circuits, including LSI (Large-Scale Integration) for automotive applications and others. In model-based design, a user creates a first model representing the circuit to be designed (hereinafter referred to as the "target circuit") and inputs the created first model into a simulator. The simulator simulates the operation of the first model. This allows the user to verify the operation of the first model.

Additionally, conversion tools are known that have the function of converting the first model into a second model with a different level of abstraction or into a second model with the same level of abstraction. This allows the user to also verify the operation of the second model automatically generated from the first model by the conversion tool.

### SUMMARY

Generally, the equivalence between the first model and the second model automatically generated from the first model is not guaranteed. Therefore, the user needs to verify the equivalence between the first model and the second model. There is a desire to reduce the effort and time required for this verification.

Other problems and novel features will become apparent from the description herein and from the accompanying drawings.

An information processing device according to one embodiment includes a storage unit that stores waveform data indicating the waveforms of multiple signals output from a first simulator that simulates the operation of a first model representing a target circuit. The multiple signals include a clock signal. The information processing device further includes: a determination unit that determines, by analyzing the waveform data, a mask time period during which one or more analysis target signals other than the clock signal among the multiple signals do not fluctuate; and a generation unit that generates an input signal to a second simulator that simulates the operation of a second model obtained by converting the first model. Here, the level of abstraction of the second model may be different from or the same as that of the first model. The generation unit generates a masked clock signal as an input signal by masking the mask time period in the clock signal.

A system according to another embodiment includes: a first simulator that simulates the operation of a first model representing a target circuit; a converter that converts the first model into a second model; a second simulator that simulates the operation of the second model; and a storage unit that stores waveform data indicating the waveforms of multiple signals output from the first simulator. The multiple signals include a clock signal. The system further includes a determination unit that determines, by analyzing the waveform data, a mask time period during which one or more analysis target signals other than the clock signal among the multiple signals do not fluctuate, and a generation unit that generates an input signal to the second simulator. Here, the level of abstraction of the second model may be different from or the same as that of the first model. The generation unit generates a masked clock signal as an input signal by masking the mask time period in the clock signal.

An information processing method according to another embodiment includes reading waveform data indicating the waveforms of multiple signals output from a first simulator that simulates the operation of a first model representing a target circuit. The multiple signals include a clock signal. The information processing method further includes determining, by analyzing the waveform data, a mask time period during which one or more analysis target signals other than the clock signal among the multiple signals do not fluctuate and generating an input signal to a second simulator that simulates the operation of a second model obtained by converting the first model. Here, the level of abstraction of the second model may be different from or the same as that of the first model. Generating includes generating a masked clock signal as an input signal by masking the mask time period in the clock signal.

A program according to another embodiment causes a computer to execute the above information processing method.

According to each of the above embodiments, the effort and time required for verifying the equivalence between the first model and the second model are reduced.

### BRIEF DESCRIPTION OF THE DRAWINGS

FIG. 1 is a diagram illustrating an example of the overall configuration of a computing system according to an embodiment.

FIG. 2 is a diagram illustrating the functional configuration of a setting unit according to a reference form.

FIG. 3 is a diagram illustrating a first example of the functional configuration of a setting unit according to an embodiment.

FIG. 4 shows examples of multiple signals output from an RTL simulator.

FIG. 5 shows examples of multiple input signals to a model simulator.

FIG. 6 is a flowchart illustrating the process flow of the setting unit according to the first example.

FIG. 7 is a diagram illustrating a second example of the functional configuration of a setting unit according to an embodiment.

FIG. 8 is a diagram illustrating a third example of the functional configuration of a setting unit according to an embodiment.

FIG. 9 is a diagram illustrating a fourth example of the functional configuration of a setting unit according to an embodiment.

### DETAILED DESCRIPTION

Below, embodiments of the present disclosure will be described in detail with reference to the drawings. Note that the same or equivalent parts are denoted by the same reference numerals, and their descriptions will not be repeated.

### Overall System Configuration

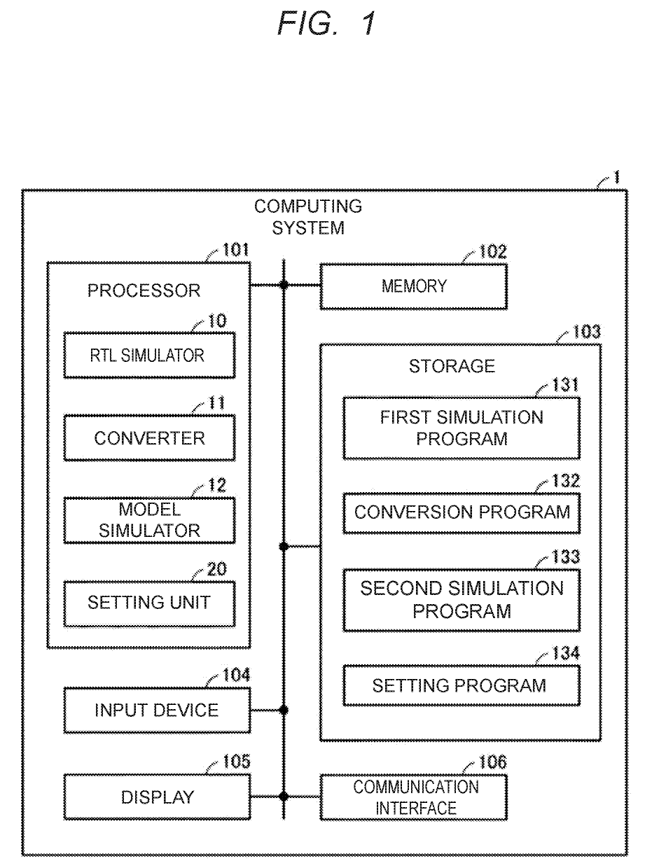

FIG. 1 is a diagram illustrating an example of the overall configuration of a computing system according to an embodiment. Computing system 1 can be realized as one or more computers, virtual machines built on a cloud environment, or a combination thereof.

Computing system 1 includes a processor 101, memory 102, storage 103, input device 104, display 105, and communication interface 106. The number of each of the processor 101, memory 102, storage 103, input device 104, display 105, and communication interface 106 is not limited to one and may be multiple.

The processor 101 includes a CPU (Central Processing Unit) or MPU (Micro Processing Unit), or the like. Processor 101 reads a program stored in storage 103 and deploys it in memory 102. Processor 101 executes the deployed program. Note that if the computing system 1 is realized by multiple computers, the processor 101 may include multiple processors provided by multiple computers.

Memory 102 includes a volatile storage device such as DRAM (Dynamic Random Access Memory) or SRAM (Static Random Access Memory).

The storage 103 includes a non-volatile storage device such as an HDD (Hard Disc Drive), SSD (Solid State Drive), or flash memory. The storage 103 stores programs executed by processor 101.

Specifically, the storage 103 stores a first simulation program 131, a conversion program 132, a second simulation program 133, and a setting program 134.

The first simulation program 131 includes a set of instructions to simulate the operation of a first model representing a target circuit. The conversion program 132 includes a set of instructions to convert the first model into a second model. Here, the abstraction level of the second model may be different from or the same as that of the first model. The second simulation program 133 includes a set of instructions to simulate the operation of the second model. The setting program 134 includes a set of instructions to set a test bench for the second model.

The first model is described, for example, at the Register Transfer Level (RTL). The first model is created using known design tools. The second model is described, for example, in SystemC or C++. In this example, the abstraction level of the second model is higher than that of the first model. Below, an example where the first model is described in RTL and the second model is described in SystemC or C++ will be explained. However, the description level for the first model is not limited to RTL. Also, the hardware description language for describing the second model is not limited to SystemC or C++. Even if the abstraction level of the second model is the same as or lower than that of the first model, the computing system according to the present disclosure can be implemented based on the same principles as described below.

The processor 101 can operate as an RTL simulator 10, a converter 11, a model simulator 12, and a setting unit 20. The RTL simulator 10 is realized by processor 101 executing the first simulation program 131. The converter 11 is realized by processor 101 executing the conversion program 132. The model simulator 12 is realized by processor 101 executing the second simulation program 133. Setting unit 20 is realized by processor 101 executing the setting program 134. As described above, computing system 1 can be realized as one or more computers, virtual machines, or a combination thereof. A computer or virtual machine operating as the setting unit 20 corresponds to the "information processing device" of the present disclosure.

The RTL simulator 10 simulates the operation of the first model described in RTL. The RTL simulator 10 outputs multiple signals as simulation results. The RTL simulator 10 is an example of the "first simulator" of the present disclosure. The multiple signals include a clock signal. Furthermore, the multiple signals include signals at each of one or more nodes included in the target circuit.

The converter 11 converts the first model into the second model. In other words, the converter 11 automatically generates the second model from the first model. The converter 11 is realized, for example, by known tools. Known tools include, for example, "Verilator". "Verilator" converts a logically-synthesizable model written in Verilog (registered trademark), one of the hardware description languages, into a model described in SystemC or C++. Verilog is used to design circuits at the RTL.

The model simulator 12 simulates the operation of the second model described in SystemC or C++. The model simulator 12 is an example of the "second simulator" of the present disclosure.

The setting unit 20 sets a test bench for the second model. To verify the equivalence between the first model and the second model, it is preferable to port the same test bench used for the first model to the second model. Therefore, the setting unit 20 sets a test bench for the second model corresponding to the test bench for the first model.

The input device 104 includes a keyboard, mouse, or touch panel, among others. The input device 104 outputs the input information to the processor 101. The display 105 displays a screen indicated by the screen data generated by the processor 101.

The communication interface 106 communicates with external devices via a communication network. The communication interface 106 may install the first simulation program 131, conversion program 132, second simulation program 133, and setting program 134 from an external server to the computing system 1.

### Functional Configuration and Issues of the Setting Unit According to a Reference Form

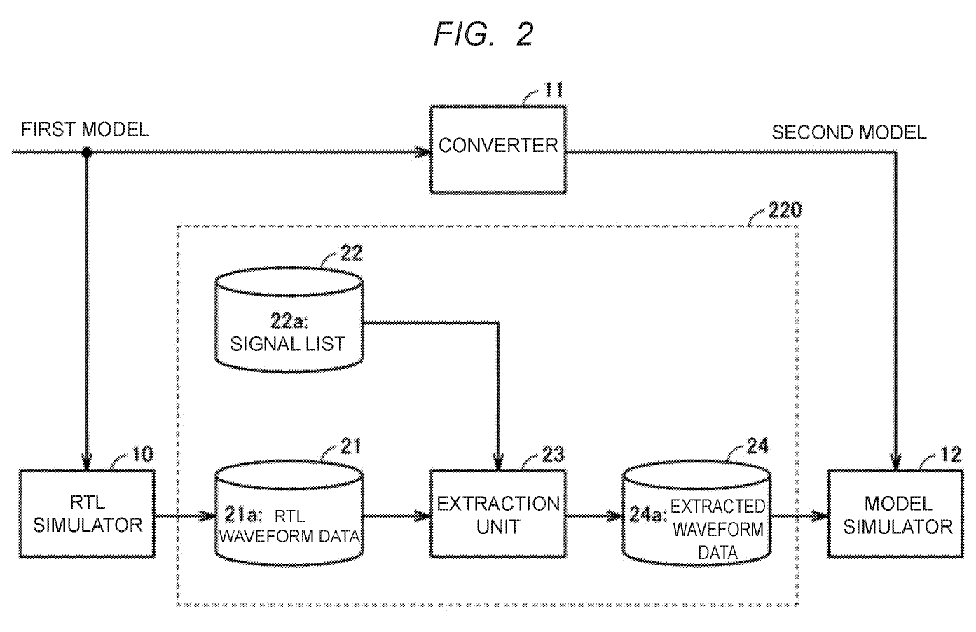

Before explaining the functions of setting unit 20 according to the embodiment, the functional configuration and issues of the setting unit according to a reference form will be explained with reference to FIG. 2. FIG. 2 is a diagram showing the functional configuration of the setting unit according to a reference form. The setting unit 220 according to the reference form sets a test bench for the second model corresponding to the test bench for the first model, similar to the setting unit 20 according to the embodiment.

As shown in FIG. 2, the setting unit 220 according to the reference form includes storage units 21, 22, 24, and an extraction unit 23.

The storage unit 21 stores RTL waveform data 21a representing the simulation results of the operation of the first model. The RTL waveform data 21a shows the waveform of each of the multiple signals output from the RTL simulator 10. That is, the RTL waveform data 21a indicates information identifying a signal (e.g., signal name) and the signal value at each time for each signal.

Storage unit 22 stores a signal list 22a indicating a list of signals to be extracted. The signal list 22a is created in advance according to user operations. The signal list 22a indicates information identifying the signals to be extracted (e.g., signal name) among the multiple signals output from the RTL simulator 10. To verify the equivalence between the first model and the second model, the user may specify the signals to be applied to the second model among the multiple signals output from the RTL simulator 10 as extraction targets.

The clock signal is used to synchronize between multiple circuits included in the target circuit. The second model operates in synchronization with the clock signal, similar to the first model. Therefore, the clock signal is essential for verifying the equivalence between the first model and the second model. Accordingly, the signal list 22a includes information identifying the clock signal (hereinafter referred to as "clock identification information").

Extraction unit 23 accesses the signal list 22a. Then, the extraction unit 23 extracts one or more extraction target signals listed in the signal list 22a from the multiple signals output by the RTL simulator 10. In other words, the extraction unit 23 extracts data (hereinafter referred to as "extracted waveform data 24a") indicating the waveform of one or more extraction target signals listed in the signal list 22a from the RTL waveform data 21a. The extracted waveform data 24a is stored in storage unit 24. The extracted waveform data 24a shows information identifying the signal (e.g., signal name) and the signal value at each time for each of the one or more extraction target signals.

The extracted waveform data 24a is used as input when the model simulator 12 simulates the operation of the second model. That is, the extracted waveform data 24a is used as a test bench for the second model. As described above, the extracted waveform data 24a is extracted from the RTL waveform data 21a, which represents the simulation result of the operation of the first model by the RTL simulator 10. Therefore, the extracted waveform data 24a represents a test bench for the first model. In other words, the extracted waveform data 24a, which represents a test bench for the first model, is used as a test bench for the second model. In this way, the setting unit 220 sets the test bench for the second model to correspond to the test bench for the first model.

The model simulator 12 simulates the operation of the second model in synchronization with the clock signal indicated by the extracted waveform data 24a. That is, model simulator 12 evaluates the circuit function of the second model for each clock. In other words, the model simulator 12 needs to perform calculations according to the formula defining the circuit function of the second model for each clock. Therefore, the simulation speed by the model simulator 12 becomes slower.

### Example of Functional Configuration of Setting Unit According to Embodiment

Considering the above-mentioned problems of the setting unit according to the reference form, the setting unit according to the embodiment sets the test bench for the second model so that it corresponds to the test bench for the first model and can suppress the decrease in simulation speed by the model simulator 12. Below, the first to fourth examples of setting unit 20 according to the embodiment will be described.

### First Example

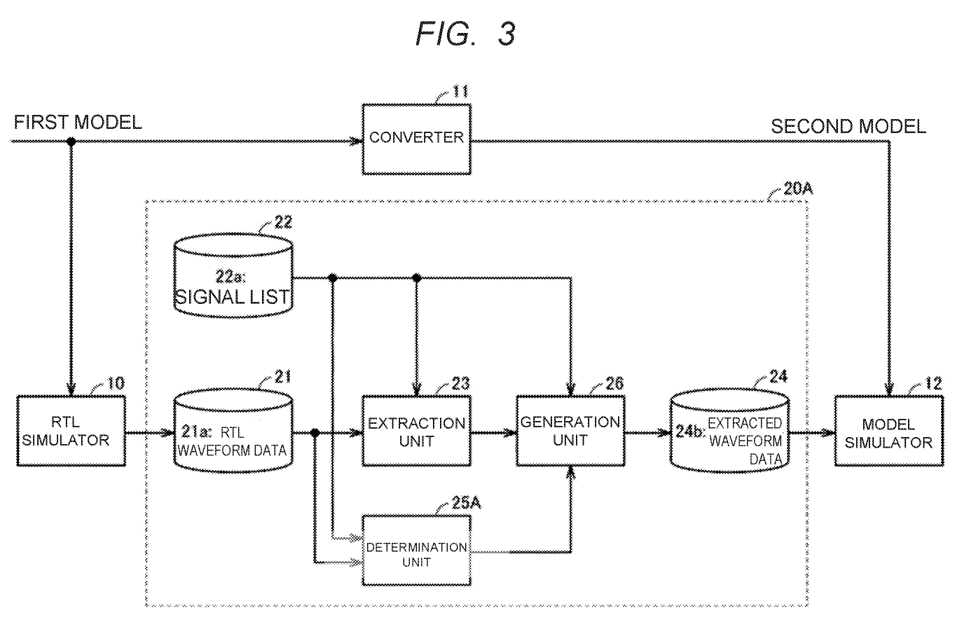

FIG. 3 is a diagram showing the first example of the functional configuration of the setting unit according to the embodiment. As shown in FIG. 3, the setting unit 20A according to the first example differs from the setting unit 220 shown in FIG. 2 in that it includes a determination unit 25A and a generation unit 26. The extraction unit 23, determination unit 25A, and generation unit 26 are realized by processor 101 shown in FIG. 1 executing the setting program 134. The storage units 21, 22, and 24 are realized by allocating specific storage areas in memory 102 or storage 103.

In the first example as well, extraction unit 23 accesses the signal list 22a and extracts one or more extraction target signals listed in the signal list 22a from the multiple signals output by the RTL simulator 10, similar to the reference form. The signal list 22a is an example of the "second signal list" of the present disclosure.

The determination unit 25A determines the mask time period during which one or more analysis target signals other than the clock signal among the multiple signals output by the RTL simulator 10 do not fluctuate.

Generation unit 26 generates input signals to the model simulator 12, which simulates the operation of the second model obtained by converting the first model. Generation unit 26 identifies signals other than the clock signal from the one or more extraction target signals extracted by the extraction unit 23 based on the clock identification information included in the signal list 22a. Generation unit 26 determines the identified signals as input signals to the model simulator 12.

Furthermore, the generation unit 26 identifies the clock signal from the one or more extraction target signals extracted by the extraction unit 23 based on the clock identification information. The generation unit 26 generates a masked clock signal as an input signal to the model simulator 12 by masking the mask time period in the clock signal. In other words, the generation unit 26 generates a clock signal with the mask time period masked as an input signal to the model simulator 12. Masking the mask time period includes fixing the signal value of the mask time period to "0" or "1". As a result, the masked clock signal does not have a clock edge during the mask time period.

Generation unit 26 stores the extracted waveform data 24b, which shows the waveform of the generated input signal, in the storage unit 24. The extracted waveform data 24b is used as input when the model simulator 12 simulates the operation of the second model.

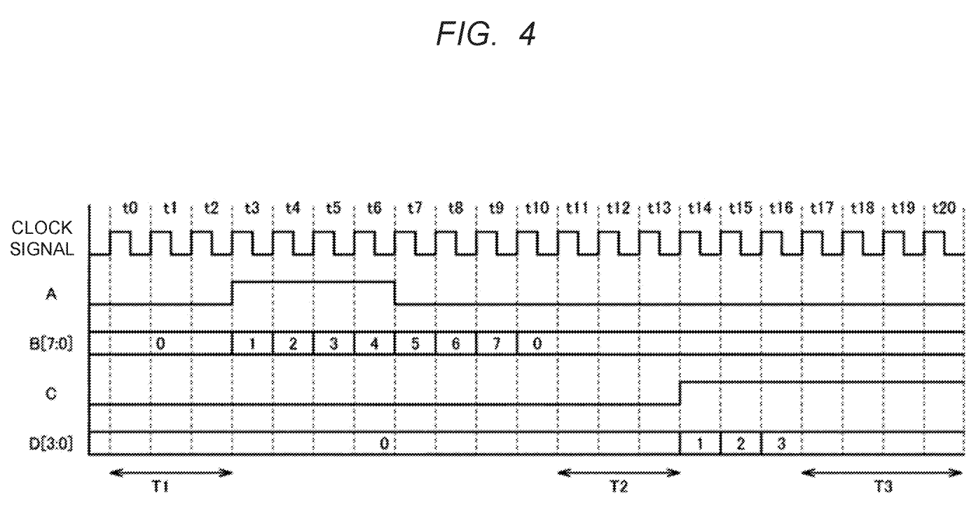

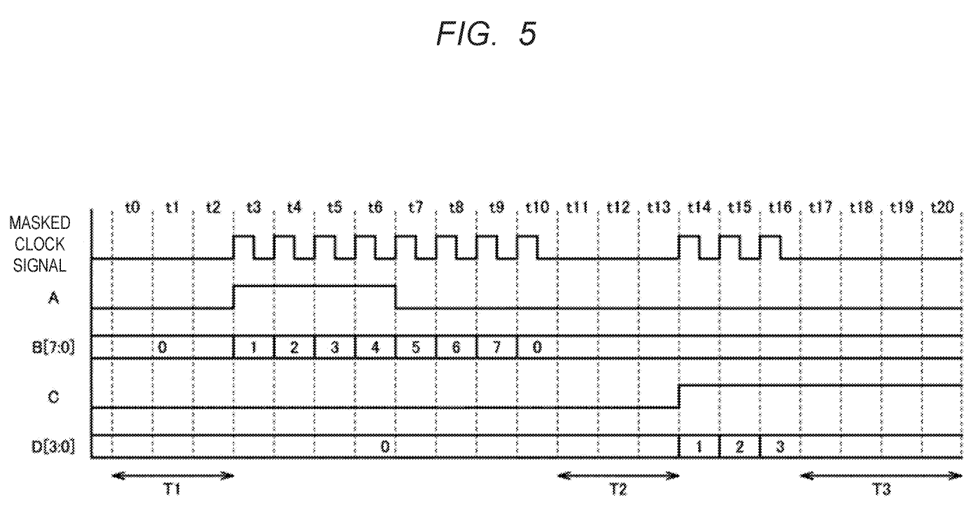

The processing of the determination unit 25A and the generation unit 26 will be described with reference to FIGS. 4 and 5. FIG. 4 shows an example of multiple signals output by the RTL simulator. FIG. 5 shows an example of multiple input signals to the model simulator.

In the example shown in FIG. 4, the multiple signals output by the RTL simulator 10 include a clock signal and signals indicating the states of nodes "A", "B", "C", and "D" included in the target circuit. The bit width of the clock signal is 1 bit. The bit width of the signals indicating the states of each node is not particularly limited. For example, the bit width of the signals indicating the states of nodes "A" and "C" is 1 bit. The bit width of the signal indicating the state of node "B" is 8 bits. The bit width of the signal indicating the state of node "D" is 4 bits.

The determination unit 25A identifies the analysis target signals other than the clock signal from the multiple signals output by the RTL simulator 10 based on the clock identification information included in the signal list 22a. In the example shown in FIG. 4, the signals indicating the states of nodes "A", "B", "C", and "D" are identified as analysis target signals.

The determination unit 25A determines the clock period during which all the signals indicating the states of nodes "A", "B", "C", and "D" identified as analysis target signals do not fluctuate as the mask time period. A clock period during which the signal does not fluctuate is a clock period in which the signal value at the end timing of the previous clock period is continuously maintained. In the example shown in FIG. 4, the signal indicating the state of node "A" does not fluctuate in clock periods other than periods t3 and t7. The signal indicating the state of node "B" does not fluctuate in the clock periods from period t0 to period t2 and from period t11 to period t20. The signal indicating the state of node "C" does not fluctuate in clock periods other than period t14. The signal indicating the state of node "D" does not fluctuate in the clock periods from period t0 to period t13 and from period t17 to period t20. Therefore, the determination unit 25A determines the time period T1 from period t0 to period t2, the time period T2 from period t11 to period t13, and the time period T3 from period t17 to period t20 as the mask time periods.

The generation unit 26 generates a masked clock signal by masking the mask time periods (time periods T1, T2, T3) in the clock signal. In the example shown in FIG. 5, the generation unit 26 generates a masked clock signal in which the mask time periods (time periods T1, T2, T3) are "0".

According to the setting unit 20A of the first example, similar to the setting unit 220 according to the reference form, the data extracted from the RTL waveform data 21a, which represents the simulation result of the operation of the first model, is used as input when simulating the operation of the second model. Therefore, the setting unit 20 can set the test bench for the second model to correspond to the test bench for the first model.

Furthermore, the clock signal with the mask time period masked is input to the model simulator 12. The model simulator 12 performs calculations to evaluate the circuit function of the second model in synchronization with the clock edge of the clock signal. Since the clock signal with the mask time period masked is input, the model simulator 12 does not evaluate the circuit function of the second model during the mask time period. The mask time period is a time period during which one or more analysis target signals do not fluctuate. Therefore, it is expected that the circuit function of the second model will not fluctuate during the mask time period. Consequently, calculations for evaluating the circuit function of the second model during the mask time period are unnecessary. According to the setting unit 20A of the first example, unnecessary calculations during the mask time period are reduced, thereby suppressing the decrease in simulation speed by the model simulator 12. In other words, the model simulator 12 can simulate the operation of the second model at high speed.

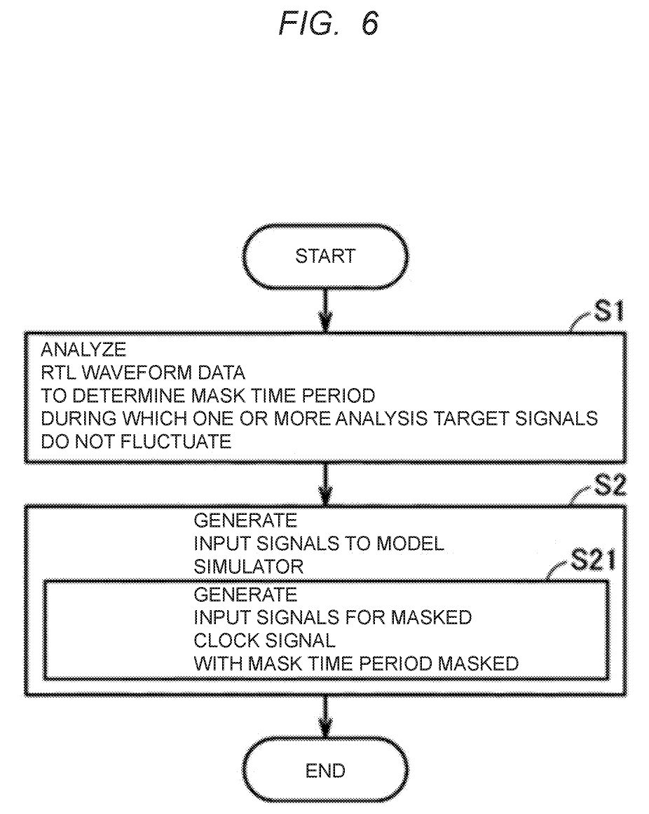

FIG. 6 is a flowchart showing the process flow of the setting unit according to the first example. In step S1, the processor 101 operating as the determination unit 25A reads the RTL waveform data 21a, which shows the waveform of multiple signals output by the RTL simulator 10. Then, the processor 101 analyzes the RTL waveform data 21a to determine the mask time period during which one or more analysis target signals other than the clock signal do not fluctuate among the multiple signals.

In step S2, the processor 101 operating as the generation unit 26 generates input signals to the second simulator that simulates the operation of the second model. Step S2 includes step S21, which generates input signals to the clock signal with the mask time period masked. Furthermore, step S2 includes the step of incorporating one or more extraction target signals (excluding clock signals) extracted from multiple signals based on the signal list 22a into the input signals to the model simulator 12.

### Second Example

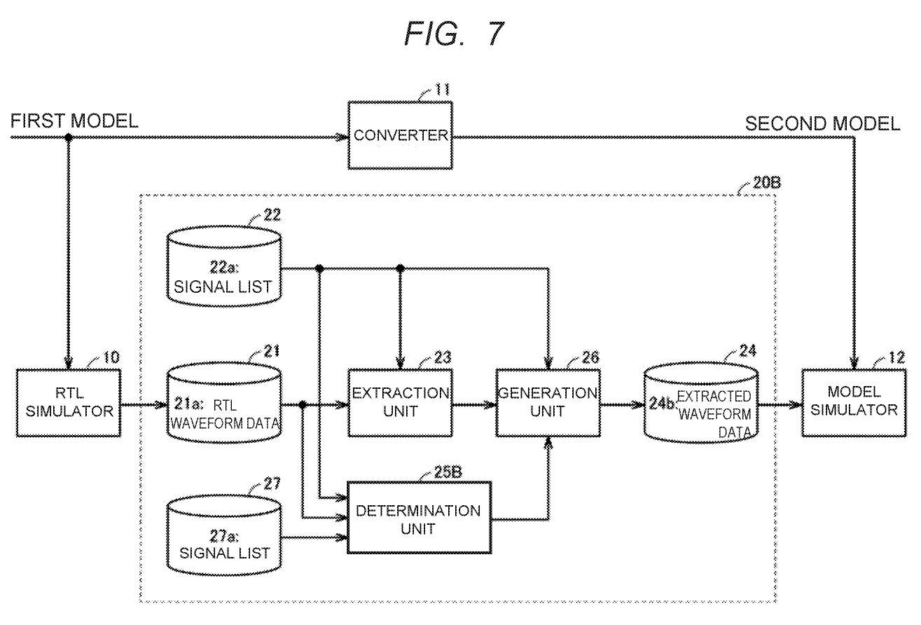

FIG. 7 is a diagram showing a second example of the functional configuration of the setting unit according to the embodiment. As shown in FIG. 7, the setting unit 20B according to the second example differs from the setting unit 20A shown in FIG. 3 in that it includes a determination unit 25B instead of the determination unit 25A, and it includes a storage unit 27. Determination unit 25B is implemented by processor 101 shown in FIG. 1 executing the setting program 134. Storage unit 27 is implemented by allocating a specific storage area in memory 102 or storage 103.

Storage unit 27 stores a signal list 27a that indicates a list of signals not subject to analysis. The signal list 27a is created in advance based on the user's specification. The signal list 27a is an example of the "first signal list" of the present disclosure.

The determination unit 25B differs from the determination unit 25A of the first example only in that it excludes signals included in the signal list 27a from the one or more analysis target signals. Specifically, the determination unit 25B identifies one or more signals, other than the clock signal and signals listed in the signal list 27a, as one or more analysis target signals from the multiple signals output by the RTL simulator 10.

The multiple signals output by the RTL simulator 10 may include various signals in addition to the clock signal and signals indicating the state of nodes included in the target circuit. For example, the multiple signals may include signals that invert the clock signal. The signal that inverts the clock signal fluctuates constantly in synchronization with the clock signal. Therefore, if the signal that inverts the clock signal is identified as one or more analysis target signals, there will be no mask time period during which the one or more analysis target signals do not fluctuate. Thus, the user should add the signal that inverts the clock signal to the signal list 27a. This will determine an effective mask time period.

Furthermore, the user may appropriately add signals that do not affect the simulation of the operation of the second model to the signal list 27a from the multiple signals output by the RTL simulator 10. This also determines an effective mask time period.

According to the setting unit 20B of the second example, similar to the first example, the test bench for the second model is set to correspond to the test bench for the first model. Additionally, by determining an effective mask time period, the model simulator 12 can simulate the operation of the second model more quickly.

### Third Example

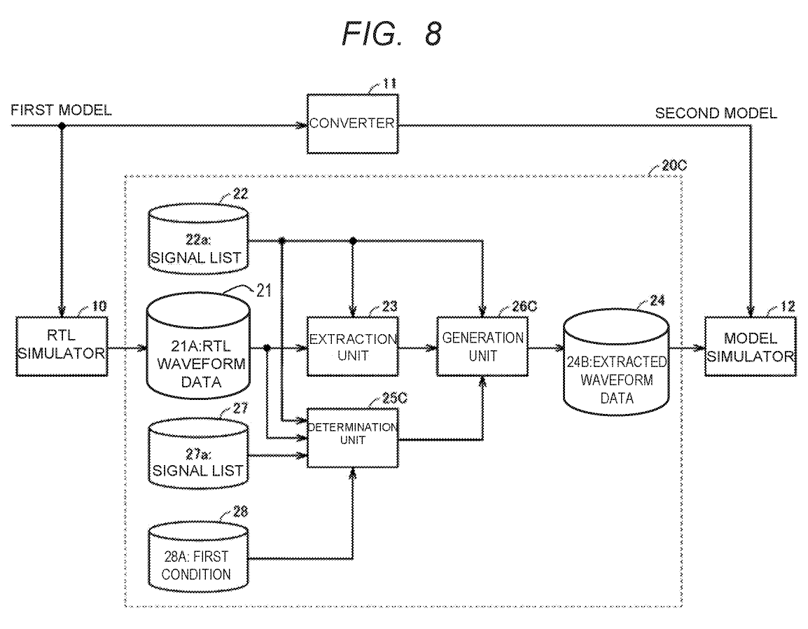

FIG. 8 is a diagram showing a third example of the functional configuration of the setting unit according to the embodiment. As shown in FIG. 8, the setting unit 20C of the third example differs from the setting unit 20B shown in FIG. 7 in that it includes the determination unit 25C and the generation unit 26C instead of the determination unit 25B and the generation unit 26 and includes the storage unit 28. The determination unit 25C and the generation unit 26C are realized by processor 101 shown in FIG. 1 executing the setting program 134. Storage unit 28 is realized by allocating a specific storage area in memory 102 or storage 103.

The storage unit 28 stores the first condition 28a for determining the time period to be added to the mask time period. The first condition 28a is created in advance based on the user's specification.

The determination unit 25C differs from the determination unit 25B of the second example only in that it further determines additional time periods where one or more analysis target signals satisfy the first condition 28a. The determination unit 25C outputs the additional time periods to the generation unit 26C in addition to the mask time period.

The generation unit 26C differs from the generation unit 26 of the first and second examples only in that it generates a masked clock signal as an input signal to the model simulator 12 by masking the additional time periods in addition to the masked time period in the clock signal.

The first condition 28a may include, for example, a condition that the signal indicating the state of node "A" is "0". Alternatively, the first condition 28a may define a combination of values of two or more signals. For example, the first condition 28a may include a condition that both the signal indicating the state of node "B" and the signal indicating the state of node "C" are "0".

For example, the multiple signals output by the RTL simulator 10 may include signals representing the temporary suspension of the operation of the target circuit. In such cases, the user should set the condition that the signal indicates a value corresponding to the suspension as the first condition 28a. This will determine the time period during which the operation of the target circuit is suspended as an additional time period. As a result, the model simulator 12 will not evaluate the circuit functions of the second model during the additional time period.

According to the setting unit 20B of the third example, similar to the first and second examples, the test bench for the second model is set to correspond to the test bench for the first model. Furthermore, since unnecessary calculations during the additional time period are reduced in addition to the mask time period, the model simulator 12 can simulate the operation of the second model more quickly.

Note that it is acceptable that the setting unit 20C of the third example does not include storage unit 27. In this case, the determination unit 25C omits the process of excluding signals included in the signal list 27a from the one or more analysis target signals.

### Fourth Example

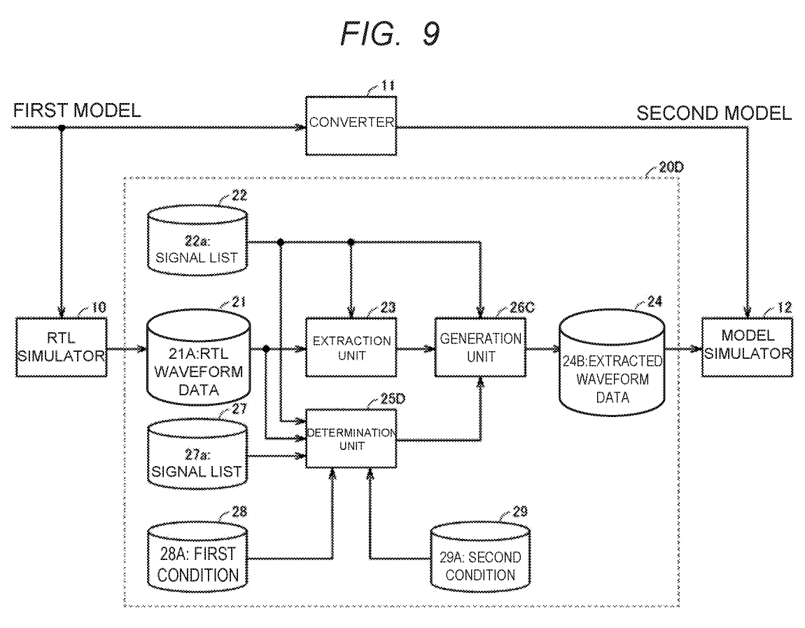

FIG. 9 is a diagram showing a fourth example of the functional configuration of the setting unit according to the embodiment. As shown in FIG. 9, the setting unit 20D of the fourth example differs from the setting unit 20C shown in FIG. 8 in that it includes the determination unit 25D instead of the determination unit 25C and includes the storage unit 29. The determination unit 25D is realized by the processor 101 shown in FIG. 1 executing the setting program 134. Storage unit 29 is realized by allocating a specific storage area in memory 102 or storage 103.

The storage unit 29 stores the second condition 29a for determining the time period to be excluded from the mask time period. The second condition 29a is created in advance based on the user's specification.

The determination unit 25D differs from the determination unit 25C of the third example only in that it excludes the exclusion time periods where one or more analysis target signals satisfy the second condition 29a from the mask time period. The determination unit 25D outputs the mask time period from which the exclusion time periods have been excluded to the generation unit 26C.

The second condition 29a may include, for example, a condition that the signal indicating the state of node "A" is "0". Alternatively, the second condition 29a may define a combination of values of two or more signals. For example, the second condition 29a may include a condition that both the signal indicating the state of node "B" and the signal indicating the state of node "C" are "0".

It could happen that the operation of the second model simulated by the model simulator 12 based on the clock signal with the mask time period masked is not as expected by the user. For example, events such as the operation of the second model not synchronizing with the operation of the first model, the operation of the second model not being the same logic as the first model, or the output result of the second model deviating from the output result of the first model may occur. Such problem events may be due to the omission of calculations during the mask time period. Therefore, the user sets the condition defining the period during which problem events occur as the second condition 29a. This will exclude the period during which problem events occur from the mask time period. As a result, issues caused by setting the mask time period may be resolved.

Note that it is acceptable that the setting unit 20D of the fourth example does not include storage unit 27. In this case, the determination unit 25D omits the process of excluding signals included in the signal list 27a from the one or more analysis target signals. Also, it is acceptable that the setting unit 20D of the fourth example does not include storage unit 28. In this case, the determination unit 25D omits the process of determining additional time periods where one or more analysis target signals satisfy the first condition 28a.

### Modified Example

The multiple signals output by the RTL simulator 10 may include multiple clock signals. In this case, the determination units 25A, 25B, 25C, and 25D may determine a common mask time period for the multiple clock signals. Alternatively, the determination units 25A, 25B, 25C, and 25D may determine a mask time period for each clock signal.

For example, the determination unit 25A may identify one or more analysis target signals for each clock signal. The correspondence between the clock signals and the one or more analysis target signals is predetermined based on the user's specification. Determination unit 25A determines the mask time period for each clock signal based on the corresponding one or more analysis target signals to each clock signal.

Alternatively, the signal list 27a may indicate signals that are not analysis targets for each clock signal. In this case, the determination unit 25B identifies one or more analysis target signals for each clock signal based on the signal list 27a. Then, the determination unit 25B determines the mask time period for each clock signal based on the corresponding one or more analysis target signals.

The first condition 28a or the second condition 29a may be set for each clock signal. Alternatively, the first condition 28a or the second condition 29a may be set only for specific clock signals. For example, the determination unit 25C may determine additional time periods in which one or more analysis target signals satisfy the first condition 28a only for specific clock signals. Alternatively, the determination unit 25D may exclude exclusion time periods, in which one or more analysis target signals satisfy the second condition 29a, from the mask time periods only for specific clock signals.

Although the invention made by the present inventor has been specifically described based on the embodiment, the present invention is not limited to the above-described embodiment, and it is needless to say that various modifications can be made without departing from the gist thereof.

What is claimed is:

1. An information processing device comprising:
a storage unit that stores waveform data indicating waveforms of a plurality of signals output from a first simulator that simulates an operation of a first model representing a target circuit, wherein the plurality of signals includes a clock signal;
a determination unit that determines, by analyzing the waveform data, a mask period during which one or more analysis target signals other than the clock signal among the plurality of signals do not fluctuate; and
a generation unit that generates an input signal to a second simulator that simulates an operation of a second model obtained by converting the first model,
wherein the generation unit generates a masked clock signal as the input signal by masking the mask period in the clock signal.

2. The information processing device according to claim 1, wherein the determination unit accesses a first signal list and excludes signals included in the first signal list from the one or more analysis target signals.

3. The information processing device according to claim 2, wherein the first signal list includes a signal obtained by inverting the clock signal.

4. The information processing device according to claim 1,
wherein the determination unit further determines an additional period during which the one or more analysis target signals satisfy a predetermined first condition, and
wherein the generation unit generates the masked clock signal by masking the additional period in addition to the mask period in the clock signal.

5. The information processing device according to claim 1, wherein the determination unit excludes a period during which the one or more analysis target signals satisfy a predetermined second condition from the mask period.

6. The information processing device according to claim 1, further comprising an extraction unit that accesses a second signal list and extracts one or more extraction target signals included in the second signal list from the plurality of signals, wherein the input signal includes the one or more extraction target signals.

7. The information processing device according to claim 1, wherein the plurality of signals includes signals at each of one or more nodes included in the target circuit.

8. The information processing device according to claim 1, wherein the first model is described at a register transfer level.

9. The information processing device according to claim 1, wherein the second model is described in SystemC or C++.

10. A system comprising:
a first simulator that simulates an operation of a first model representing a target circuit;
a converter that converts the first model into a second model;
a second simulator that simulates an operation of the second model;
a storage unit that stores waveform data indicating waveforms of a plurality of signals output from the first simulator, wherein the plurality of signals includes a clock signal;
a determination unit that determines, by analyzing the waveform data, a mask period during which one or more analysis target signals other than the clock signal among the plurality of signals do not fluctuate; and
a generation unit that generates an input signal to the second simulator,
wherein the generation unit generates a masked clock signal as the input signal by masking the mask period in the clock signal.

11. An information processing method comprising:
reading waveform data indicating waveforms of a plurality of signals output from a first simulator that simulates an operation of a first model representing a target circuit, wherein the plurality of signals includes a clock signal;
determining, by analyzing the waveform data, a mask period during which one or more analysis target signals other than the clock signal among the plurality of signals do not fluctuate; and
generating an input signal to a second simulator that simulates an operation of a second model obtained by converting the first model,
wherein the generating includes generating a masked clock signal as the input signal by masking the mask period in the clock signal.
